(19) United States
(12) Patent Application Publication
(10) Pub. No.: US 2024/0063294 A1
(43) Pub. Date: Feb. 22, 2024

(54) SEMICONDUCTOR DEVICE STRUCTURE AND METHOD FOR FORMING THE SAME

(71) Applicant: TAIWAN SEMICONDUCTOR MANUFACTURING COMPANY, LTD., Hsinchu (TW)

(72) Inventors: Ta-Chun LIN, Hsinchu (TW); Jyun-Yang SHEN, Kaohsiung (TW); Hsiang-Yu LAI, Hsinchu (TW); Shih-Chang TSAI, Hsinchu (TW); Chun-Jun LIN, Hsinchu (TW); Kuo-Hua PAN, Hsinchu (TW); Jhon Jhy LIAW, Hsinchu (TW)

(21) Appl. No.: 17/891,439

(22) Filed: Aug. 19, 2022

(51) Int. Cl. H01L 29/66; H01L 21/3065; H01L 21/308

(52) U.S. Cl. CPC H01L 29/66787; H01L 29/66545; H01L 21/3065; H01L 29/66742; H01L 21/308; H01L 29/42392

(57) ABSTRACT

A method of forming a semiconductor device structure is provided. The method includes forming a plurality of dummy gates over a substrate and performing a first etch step and a second etch step on the substrate exposed between the dummy gates. The first etch step includes an anisotropic etching process and an isotropic etching process. The second includes an isotropic etching step.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate. The various material layers can also be patterned using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a fin field-effect transistor (“FinFET”) device in accordance with some embodiments.

FIGS. 2A-5A are cross-sectional views of intermediate stages in the manufacture of a FinFET device in accordance with some embodiments.

FIGS. 6A and 6B are cross-sectional views of intermediate stages in the manufacture of a FinFET device in accordance with some embodiments.

FIGS. 7A, 7B and 7C are cross-sectional views of intermediate stages in the manufacture of a FinFET device in accordance with some embodiments.

FIGS. 8A, 8B and 8C are cross-sectional views of intermediate stages in the manufacture of a FinFET device in accordance with some embodiments.

FIGS. 9A, 9B and 9C are cross-sectional views of intermediate stages in the manufacture of a FinFET device in accordance with some embodiments.

FIGS. 10A, 10B, and 10C are cross-sectional views of intermediate stages in the manufacture of a FinFET device in accordance with some embodiments.

FIGS. 11A, 11B, 11C, and 11D are cross-sectional views of intermediate stages in the manufacture of a FinFET device in accordance with some embodiments.

FIGS. 12A, 12B, and 12C are cross-sectional views of intermediate stages in the manufacture of a FinFET device in accordance with some embodiments.

FIGS. 13A, 13B, and 13C are cross-sectional views of a FinFED device in accordance with some embodiments.

FIGS. 14A and 14B are cross-sectional views of a GAA device in accordance with some embodiment.

FIGS. 15A to 15G are cross-sectional views showing the process of forming source/drain regions using multi-step etch.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will be described with respect to a specific context, namely, a FinFET device and a method of forming the same. Various embodiments discussed herein allow for forming source/drain regions of a FinFET device, such that channel resistance may be maintained with a substantially constant value from the top to the bottom. Various embodiments presented herein are discussed in the context of FinFETs formed using a gate-last process. Embodiments for forming source/drain regions of a gate-all-around (GAA) FET is also described. In other embodiments, a gate-first process may be used. Also, some embodiments contemplate aspects used in planar devices, such as planar FETs.

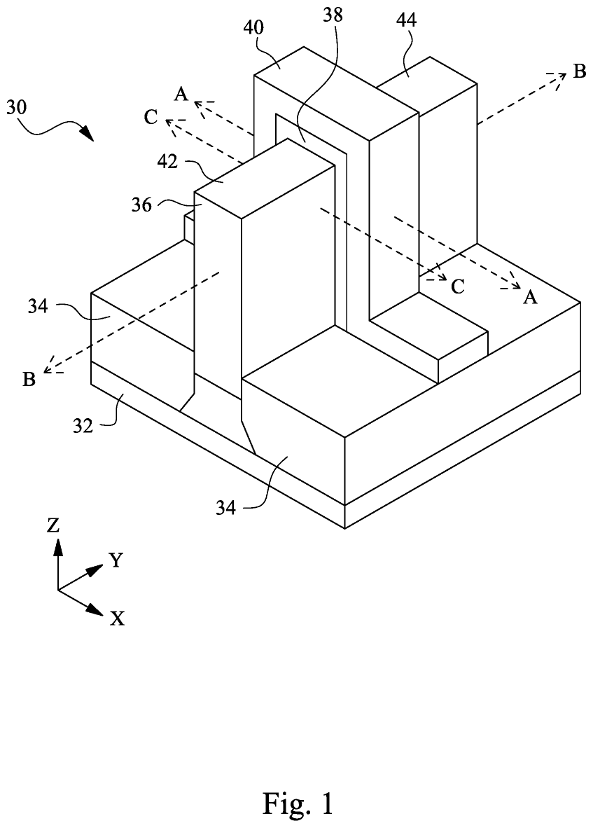

FIG. 1 is a perspective view of an exemplary fin field-effect transistor (FinFET) 30 according to one embodiment. The FinFET 30 comprises a fin 36 on a substrate 32. The substrate 32 includes isolation regions 34 and a fin 36 protrudes from the substrate 32. The fin 36 includes a bottom portion sandwiched between the neighboring regions 34 and an upper portion extending above the isolation regions 34. A gate dielectric layer 38 is formed along a top surface and two opposite sidewalls of the upper portion of the fin 36. A gate electrode 40 is over the gate dielectric layer 38. Both the gate electrode 40 and the gate dielectric layers 39 are formed conformal to the fin 36 on the XZ plane in the embodiment as shown in FIG. 1.

Source/drain regions 42 and 44 are disposed in opposite sides of the fin 36 with respect to the gate dielectric 38 and gate electrode 40. FIG. 1 further illustrates reference cross-sections that are used in subsequent figures. Cross-section A-A is an XZ plane extending across a channel, gate dielectric 38, and gate electrode 40 of the FinFET 30 along the X-axis. Cross-section C-C is in a plane parallel to cross section A-A and across the fin 36 outside of the channel along the X-axis. Cross-section B-B is perpendicular to cross-section A-A along the Y-axis along which a current flow between the source/drain regions 42 and 44. Subsequent figures refer to these reference cross-sections for clarity.

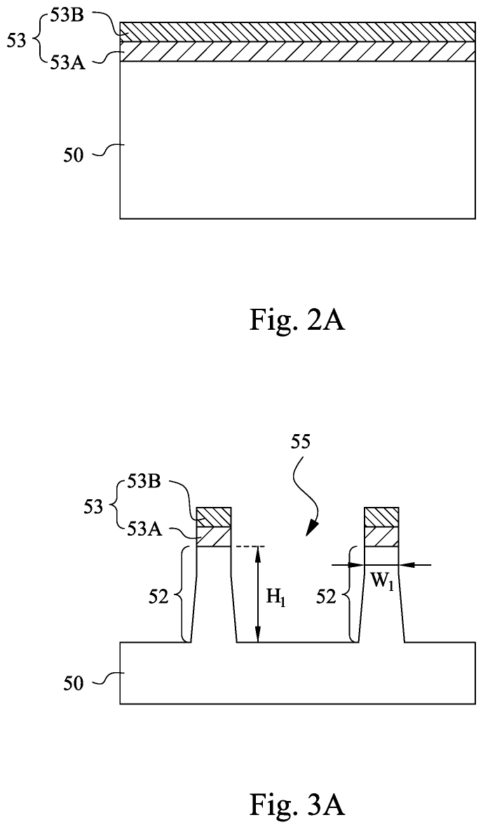

FIGS. 2A through 13A-C are cross-sectional views of intermediate stages in the manufacturing of FinFETs in accordance with some embodiments. In FIGS. 2A through 13A-C, figures ending with an “A” designation are illustrated along the reference cross-section A-A illustrated in FIG. 1, except for multiple FinFETs and multiple fins per FinFET; figures ending with a “B” or a “D” designation are illustrated along the reference cross-section B-B illustrated in FIG. 1; and figures ending with a “C” designation are illustrated along the cross-section C-C illustrated in FIG. 1.

FIG. 2A illustrates a substrate 50. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate comprises a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GaInP, and/or GaInAsP; or combinations thereof.

The substrate 50 may further include integrated circuit devices (not shown). As one of ordinary skill in the art will recognize, a wide variety of integrated circuit devices such as transistors, diodes, capacitors, resistors, the like, or combinations thereof may be formed in and/or on the substrate 50 to generate the structural and functional requirements of the design for the resulting FinFETs. The integrated circuit devices may be formed using any suitable methods. In some embodiments, the substrate 50 may comprise a region for forming n-type devices, such as NMOS transistors, such as n-type FinFETs or p-type devices, such as PMOS transistors, such as p-type FinFETs, may be formed in a similar manner.

FIG. 2A further illustrates the formation of a mask 53 over the substrate 50. In some embodiments, the mask 53 may be used in a subsequent etching step to pattern the substrate 50 (See FIG. 3A). As shown in FIG. 2A, the mask 53 may include a first mask layer 53A and a second mask layer 53B. The first mask layer 53A may be a hard mask layer, may comprise silicon nitride, silicon oxynitride, silicon carbide, silicon carbonitride, a combination thereof, or the like, and may be formed using any suitable process, such as atomic layer deposition (ALD), physical vapor deposition (PVD), chemical vapor deposition (CVD), a combination thereof, or the like. The first mask layer 53A may be used to prevent or minimize etching of the substrate 50 underlying the first mask layer 53A in the subsequent etch step (See FIG. 3A). The second mask layer 53B may comprise photoresist, and in some embodiments, may be used to pattern the first mask layer 53A for use in the subsequent etching step discussed above. The second mask layer 53B may be formed by using a spin-on technique and may be patterned using acceptable photolithography techniques. In some embodiments, the mask 53 may comprise three or more mask layers.

FIG. 3A illustrates the formation of semiconductor strips 52 in the substrate 50. Mask layers 53A and 53B may be patterned with openings to expose areas of the substrate 50 where trenches 55 will be formed. An etching process may be performed to create the trenches 55 in the substrate 50 through the openings in the mask 53. The remaining portions of the substrate 50 underlying a patterned mask 53 form a plurality of semiconductor strips 52. The etching may be any acceptable etch process, such as a reactive ion etch (RIE), neutral beam etch (NBE), the like, or a combination thereof. The etch process may be anisotropic. In some embodiments, the semiconductor strips 52 may have a height H₁ between about 50 nm and about 60 nm, and a width Wibetween about 6 nm and about 8 nm.

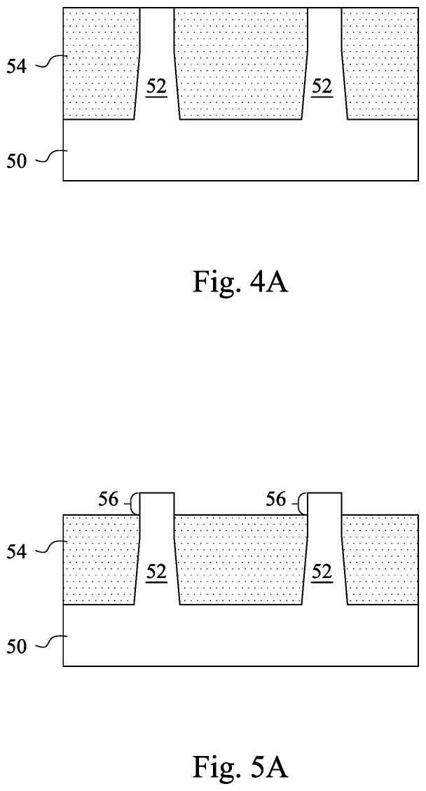

FIG. 4A illustrates the formation of an insulation material in the trenches 55 (see FIG. 3A) between neighboring semiconductor strips 52 to form isolation regions 54. The insulation material may be an oxide, such as silicon oxide, a nitride, such as silicon nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable processes may be also used.

Furthermore, in some embodiments, the isolation regions 54 may include a conformal liner (not illustrated) formed on sidewalls and a bottom surface of the trenches 55 (see FIG. 3A) prior to the filling of the trenches 55 with an insulation material of the isolation regions 54. In some embodiments, the liner may comprise a semiconductor (e.g., silicon) nitride, a semiconductor (e.g., silicon) oxide, a thermal semiconductor (e.g., silicon) oxide, a semiconductor (e.g., silicon) oxynitride, a polymer dielectric, combinations thereof, or the like. The formation of the liner may include any suitable method, such as ALD, CVD, HDP-CVD, PVD, a combination thereof, or the like. In such embodiments, the liner may prevent (or at least reduce) the diffusion of the semiconductor material from the semiconductor strips 52 (e.g., Si and/or Ge) into the surrounding isolation regions 54 during the subsequent annealing of the isolation regions 54. For example, after the insulation material of the isolation regions 54 are deposited, an annealing process may be performed on the insulation material of the isolation regions 54.

Referring further to FIG. 4A, a planarization process, such as a chemical mechanical polishing (CMP), may remove any excess insulation material of the isolation regions 54, such that top surfaces of the isolation regions 54 and top surfaces of the semiconductor strips 52 are coplanar. In some embodiments, the CMP may also remove the mask 53. In other embodiments, the mask 53 may be removed using a wet cleaning process separate from the CMP.

FIG. 5A illustrates the recessing of the isolation regions 54 to form Shallow Trench Isolation (STI) regions 54. The isolation regions 54 are recessed such that fins 56 in the region protrudes from between neighboring isolation regions 54. Further, the top surfaces of the isolation regions 54 may have a flat surface as illustrated, a convex surface, a concave surface (such as dishing), or a combination thereof. The top surfaces of the isolation regions 54 may be formed flat, convex, and/or concave by an appropriate etch. The isolation regions 54 may be recessed using an acceptable etching process, such as one that is selective to the material of the isolation regions 54.

A person having ordinary skill in the art will readily understand that the process described with respect to FIGS. 2A through 5A is just one example of how the fins 56 may be formed. In other embodiments, a dielectric layer can be formed over a top surface of the substrate 50; trenches can be etched through the dielectric layer; homoepitaxial structures can be epitaxially grown in the trenches; and the dielectric layer can be recessed such that the homoepitaxial structures protrude from the dielectric layer to form fins. In yet other embodiments, heteroepitaxial structures can be used for the fins. For example, the semiconductor strips 52 in FIG. 4A can be recessed, and a material different from the semiconductor strips 52 may be epitaxially grown in their place. In even further embodiments, a dielectric layer can be formed over a top surface of the substrate 50. Trenches can be etched through the dielectric layer. Heteroepitaxial structures can be epitaxially grown in the trenches using a material different from the substrate 50; and the dielectric layer can be recessed such that the heteroepitaxial structures protrude from the dielectric layer to form fins 56. In some embodiments where homoepitaxial or heteroepitaxial structures are epitaxially grown, the grown materials may be in situ doped during growth. In other embodiments, homoepitaxial or heteroepitaxial structures may be doped using, for example, ion implantation after homoepitaxial or heteroepitaxial structures are epitaxially grown. In some embodiments, it may be advantageous to epitaxially grow a material in a NMOS region different from the material in a PMOS region. In various embodiments, the fins 56 may comprise silicon germanium (SiₓGe₁₋ₓ, where x can be between approximately 0 and 1), silicon carbide, pure or substantially pure germanium, a III-V compound semiconductor, a II-VI compound semiconductor, or the like. For example, the available materials for forming III-V compound semiconductor include, but are not limited to, InAs, AlAs, GaAs, InP, GaN, InGaAs, InAlAs, GaSb, AlSb, AlP, GaP, and the like.

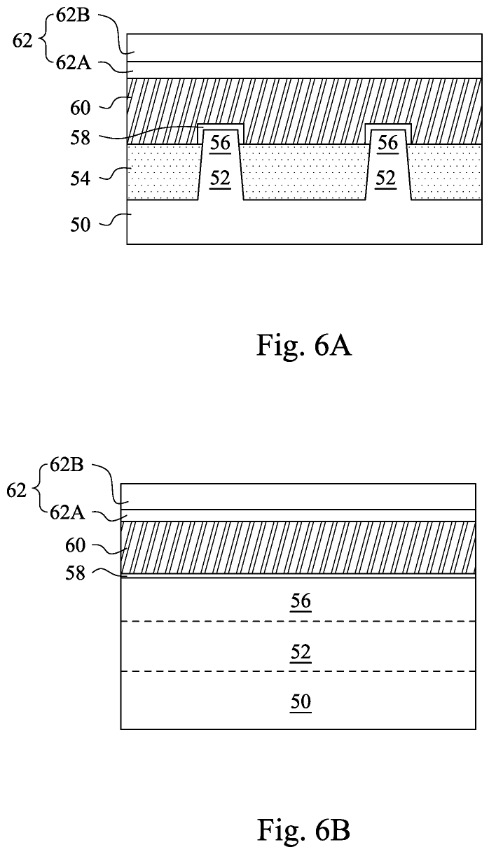

In FIGS. 6A and 6B, a dummy dielectric layer 58 is formed on the fins 56. The dummy dielectric layer 58 may be, for example, silicon oxide, silicon nitride, a combination thereof, or the like, and may be deposited (using, for example, CVD, PVD, a combination thereof, or the like) or thermally grown (for example, using thermal oxidation, or the like) according to acceptable techniques. A dummy gate layer 60 is formed over the dummy dielectric layer 58, and a mask 62 is formed over the dummy gate layer 60. In some embodiments, the dummy gate layer 60 may be deposited over the dummy dielectric layer 58 and then planarized using, for example, a CMIP process. The mask 62 may be deposited over the dummy gate layer 60. The dummy gate layer 60 may be made of, for example, polysilicon, although other materials that have a high etching selectivity with respect to the material of the isolation regions 54 may also be used. The mask 62 may include one or more layers of, for example, silicon nitride, silicon oxynitride, silicon carbide, silicon carbonitride, the like, or a combination thereof. In an embodiment, the mask 62 comprises a first mask layer 62A formed of silicon nitride and a second mask layer 62B formed of silicon oxide. In some embodiments, the first mask layer 62A may have a thickness between about 9 nm and about 13 nm, and the second mask layer 62B may have a thickness between about 110 nm and about 130 nm.

Referring further to FIGS. 6A and 6B, in the illustrated embodiment, a single dummy dielectric layer 58, a single dummy gate layer 60, and a single mask 62 are formed across the substrate. In other embodiments, separate dummy dielectric layers, separate dummy gate layers, and separate masks may be formed. In some embodiments, the dummy dielectric layer 58 may be omitted.

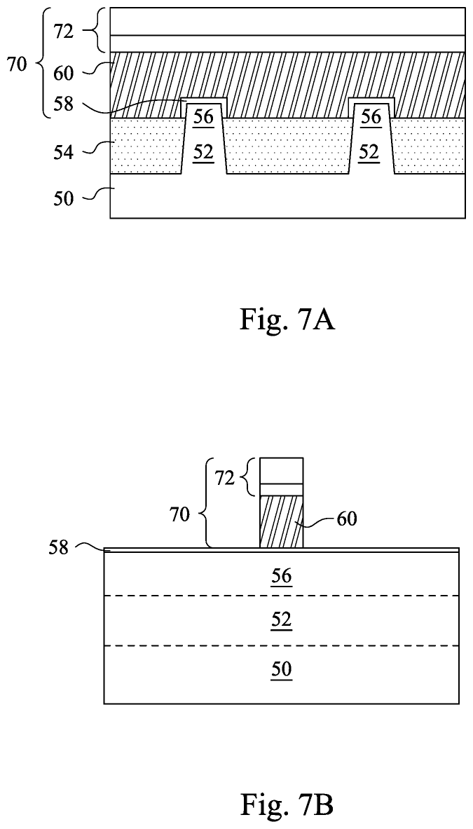

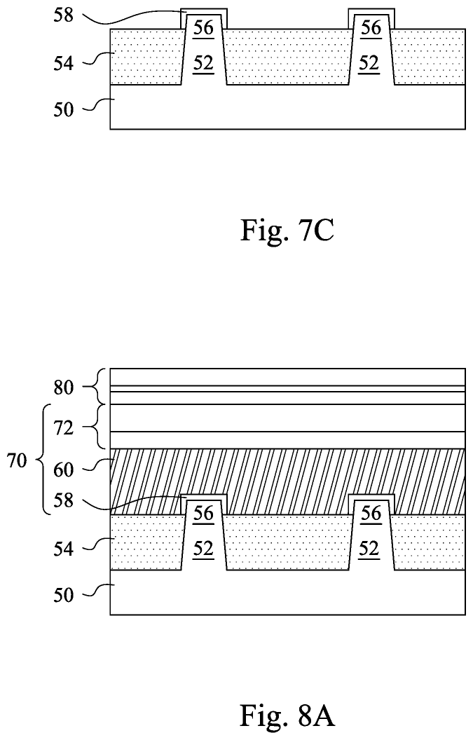

In FIGS. 7A, 7B, and 7C, the mask 62 (see FIGS. 6A and 6B) may be patterned using acceptable photolithography and etching techniques to form a mask 72. The pattern of the mask 72 then may be transferred to the dummy gate layer 60 by an acceptable etching technique to form dummy gates 70. Optionally, the pattern of the mask 72 may similarly be transferred to dummy dielectric layer 58. The pattern of the dummy gate 70 covers respective channel regions of the fins 56 while exposing source/drain regions of the fins 56. The dummy gate 70 may also have a lengthwise direction substantially perpendicular to the lengthwise direction of respective fins 56. A size of the dummy gate 70, and a pitch between dummy gates 70 and 76, may depend on a region of a die in which the dummy gates are formed. In some embodiments, the dummy gate 70 may have a larger size and a larger pitch when located in an input/output region of a die (e.g., where input/output circuitry is disposed) than when located in a logic region of a die (e.g., where logic circuitry is disposed). In some embodiments, the dummy gate 70 may have a width between about 15 nm and about 27 nm.

Referring further to FIGS. 7A, 7B and 7C, appropriate wells (not shown) may be formed in the fins 56, the semiconductor strips 52, and/or the substrate 50. For example, a P-well may be formed in the region for p-type MOS, and an N-well may be formed in the region if an n-type MOS is fabricated. When different types of regions are formed on the same substrate, different implant steps for different regions may be achieved using a photoresist or other masks (not shown).

After implanting appropriate impurities, an anneal may be performed to activate the p-type and/or n-type impurities that were implanted. The implantation process may form a P-well or an N-well. Alternatively, the implantation process may form a P-well in one region, and an N-wall in another region of the substrate. In some embodiments where the fins are epitaxial grown, the grown materials of the fins 56 may be in situ doped during the growth process.

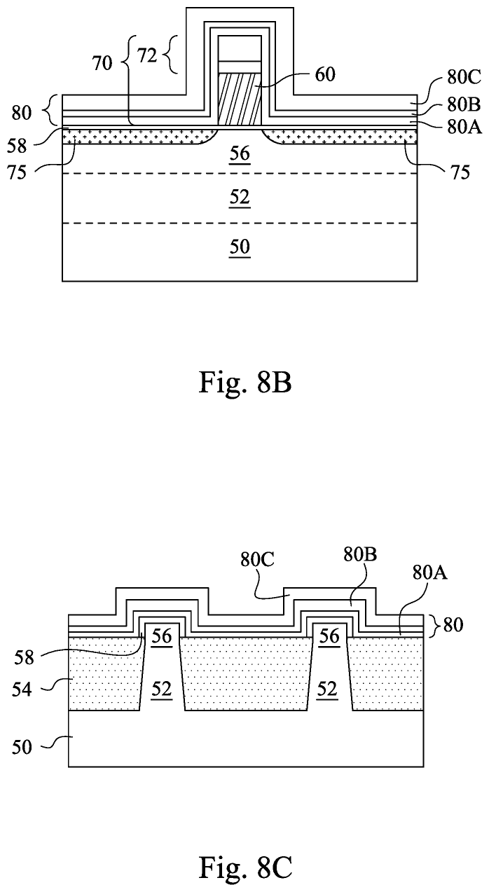

In FIGS. 8A, 8B, and 8C, a gate spacer layer 80 is formed on exposed surfaces of the dummy gates 70 and 76 (see FIGS. 8A and 8B) and/or the dummy dielectric layer 58 over the fins 56 (see FIG. 8C). Any suitable methods of forming the gate spacer layer 80 may be used. In some embodiments, a deposition (such as CVD, ALD, or the like) may be used form the gate spacer layer 80. In some embodiments, the gate spacer layer 80 may include one or more layers of, for example, silicon nitride (SiN), silicon oxynitride, silicon carbonitride, silicon oxycarbonitride (SiOCN), a combination thereof, or the like. In some embodiments, the gate spacer layer 80 may comprise a first gate spacer layer 80A, a second gate spacer layer 80B over the first gate spacer layer 80A, and a third gate spacer layer 80C of the second gate spacer layer 80B. In an embodiment, the first gate spacer layer 80A comprises SiOCN, the second gate spacer layer 80B comprises SiOCN, and the third gate spacer layer 80C comprises SiN. In some embodiment, the first gate spacer layer 80A has a thickness between about 3 nm and about 5 nm, the second gate spacer layer 80B has a thickness between about 3 nm and about 5 nm, and the third gate spacer layer 80C has a thickness between about 4 nm and about 6 nm.

Referring further to FIGS. 8A, 8B, and 8C, after forming the first spacer layer 80A, lightly doped source/drain (LDD) regions 75 may be formed. Similar to the implantation process discussed above with reference to FIGS. 7A, 7B and 7C, a mask (not shown), such as a photoresist, may be formed over a region, e.g., an NMOS region, while exposing the other region (not shown), e.g., a PMOS region, and p-type impurities may be implanted into the exposed fins 56 in the other region to create another LDD regions.

Referring further to FIGS. 8A, 8B, and 8C, after forming the LDD regions 75, the first spacer layer 80A may be carbon doped using a suitable doping process. In the illustrated embodiments, carbon doping of the first spacer layer 80A is performed after the LDD regions 75 and 79 are formed. In other embodiments, carbon doping of the first spacer layer 80A may be performed after forming the first gate spacer layer 80A, but before forming the LDD regions 75 and 79. Subsequently, the second gate spacer layer 80B is formed over the first gate spacer layer 80A, and the third gate spacer layer 80C is formed over the second gate spacer layer 80B. In some embodiments, the second spacer layer 80B may also be carbon doped using a suitable doping process. In other embodiments, the second spacer layer 80B and the third spacer layer 80C may also be carbon doped using suitable doping processes.

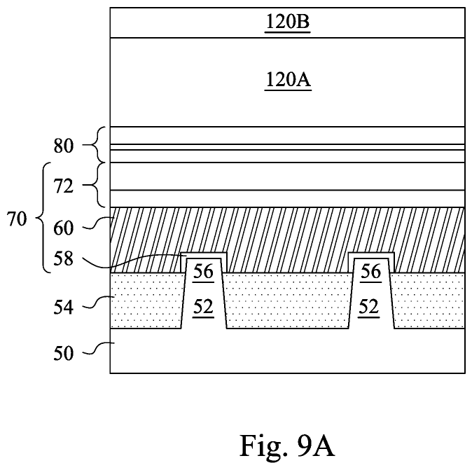

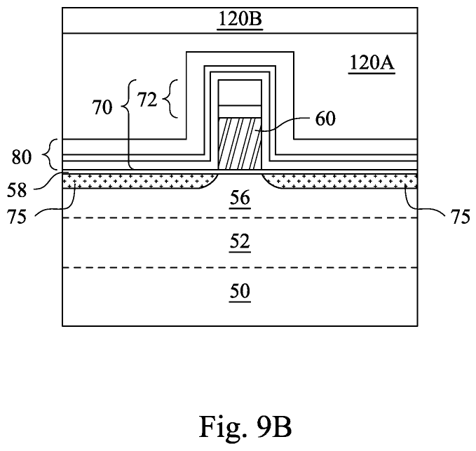

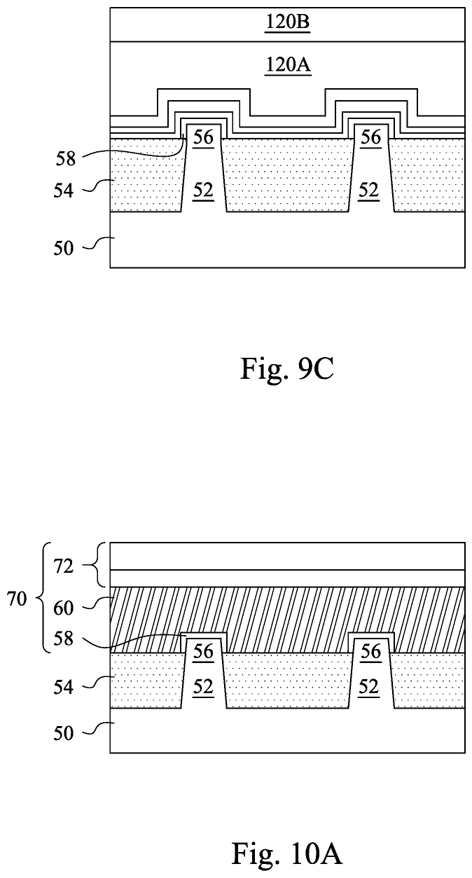

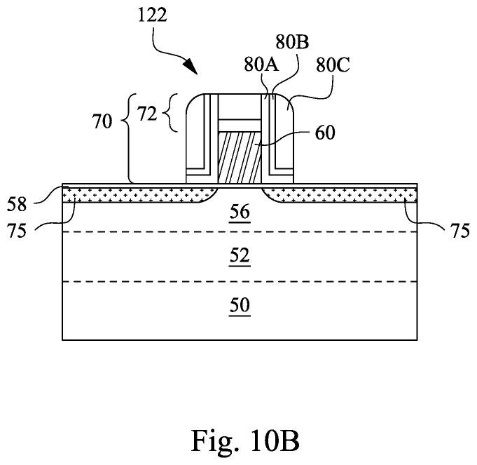

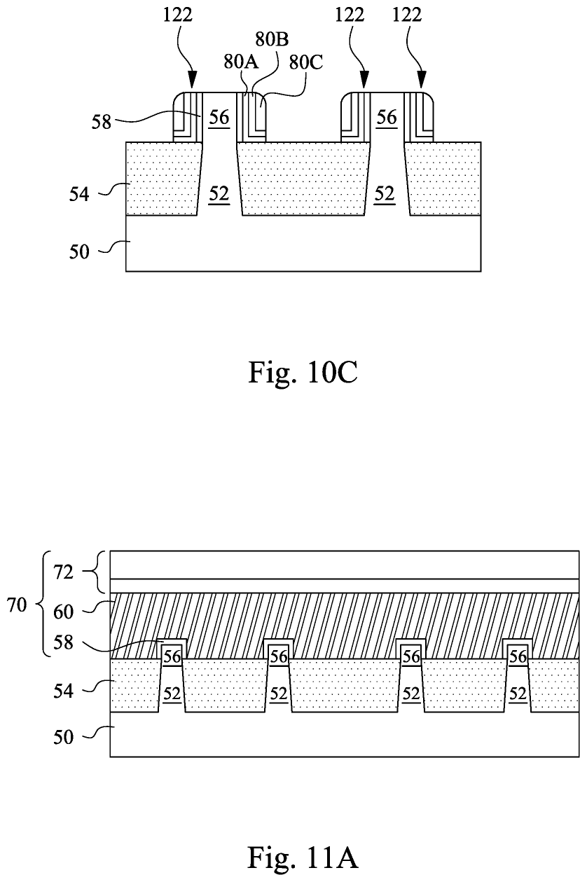

Referring to FIGS. 9A, 9B, 9C, 10A, 10B, and 10C, a patterning process is performed to remove excess portions of the spacer layer 80. Any acceptable patterning process may be used. Referring first to FIGS. 9A, 9B, and 9C, in some embodiments, a mask 120 is formed. The mask 120 may comprise a layer 120A and a layer 120B. In some embodiments, the layer 120A may comprise an organic material, such as a spin-on carbon (SOC) material, or the like, and may be formed using spin-on coating, CVD, ALD, or the like. The layer 120B may comprise an inorganic material, which may be a nitride (such as SiN, TiN, TaN, or the like), an oxynitride (such as SiON), an oxide (such as silicon oxide), or the like, and may be formed using CVD, ALD, or the like.

Referring to FIGS. 10A, 10B, and 10C, an etching process is performed using the patterned mask 120 as a mask. The etching process may be anisotropic. After preforming the etching process, lateral portions of the first spacer layer 80A, the second spacer layer 80B, and the third spacer layer 80C over the LDD regions 75 and over the isolation regions 54 may be removed to expose top surfaces of the fins 56 and the masks 72 for the dummy gate stacks 70. Portions of the first spacer layer 80A, the second spacer layer 80B, and the third spacer layer 80C along sidewalls of the dummy gates 70 and the fins 56 may remain and form spacers 122. In other embodiments, the spacer layer 80 may also be removed from the sidewalls of the fins 56. After patterning the spacer layer 80, the mask 120 may be removed using any suitable removal process.

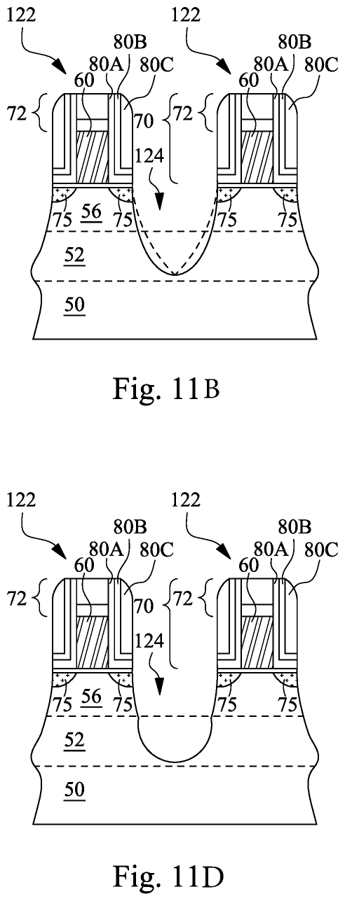

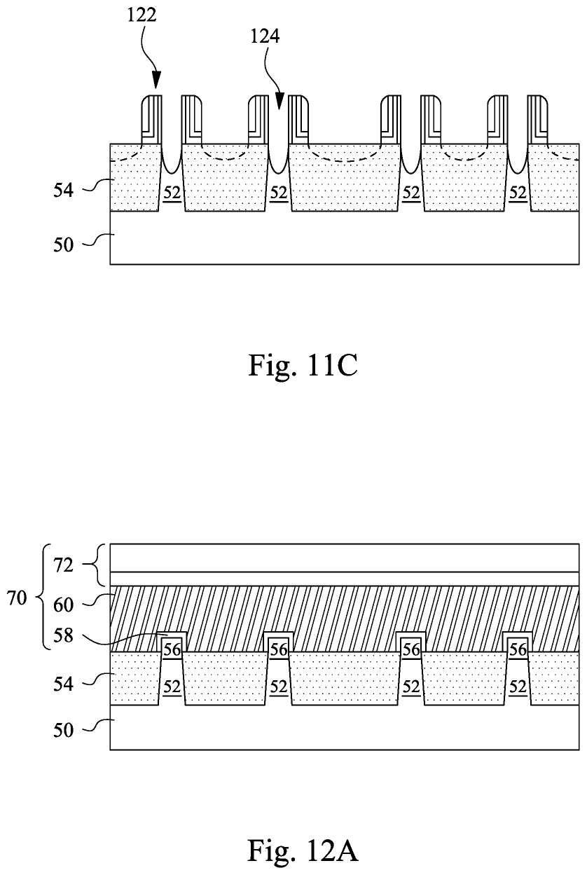

FIGS. 11A through 111D illustrate the formation of recessed regions from which epitaxial source/drain regions 82 and 84 are formed. Referring first to FIGS. 11A, 111B, 11C, and 11D, a patterning process is performed on the fins 56 to form recesses 124 in source/drain regions of the fins 56 exposed between the dummy gates 70. The patterning process may be performed in a manner that the recesses 124 are formed between neighboring dummy gates 70 (in interior regions of the fins 56), or between an isolation region 54 and adjacent dummy gate 70 as shown in the cross section illustrated in FIG. 11B and FIG. 11D.

The recesses 124 may be formed by etching the semiconductor, for example, silicon of the exposed portion of the fins 56 and the underlying semiconductor strips 52. The etch of silicon wafers may be divided into isotropy etch and anisotropy etch. Isotropic etch means that etching rate of silicon in all directions is the same during the etching process, and the etching usually results in a groove-shaped structure, for example, a long narrow channel typically in a V-shape. In contrast, anisotropic etching process typically etches silicon in a substantially vertical direction, while etching in lateral direction is negligible and insignificant. In isotropic etching, free radicals of etching gases (etchant) may be used. Random motion of the free radicals may cause the free radicals to react with silicon and remove silicon from the exposed surface. Etching rate is faster in directions with fewer atoms. Etchants used for isotropic etching may include hydrofluoric acid that etches at the same rate in all directions independently of silicon atom densities. In contrast, anisotropic etching uses heavy ions to knock off silicon atoms from the exposed surface. Silicon wafer may have a single crystal lattice that repeats in all directions, but with different densities in each direction. The vertical planes may contain a different number of silicon atoms from other planes. For etchants used for anisotropic etching such as potassium hydroxide (KOH), as the etch rate depends on the number of silicon atoms in the lattice plane, the difference in the directionally anisotropic etch rate dependent on the plane allows better control shapes etched into silicon wafers. With the corresponding orientation of silicon wafer, the duration of the etching process may be controlled to produce relatively straight or angled sides and sharp corners. Etching under the mask, that is, undercut, may also be reduced.

The recess 124 may be formed using the dummy gates 70, the spacers 122 and/or isolation regions 54 as a combined mask, an anisotropic dry etching process, for example, a reactive ion etch (RIE), neutral beam etch (NBE), the like, or a combination thereof. In some embodiments where the RIE is used in the etching process, process parameters such as a process gas mixture, a bias voltage, and an RF power may be chosen such that etching is predominantly performed using physical etching, such as ion bombardment, rather than chemical etching, such as radical etching through chemical reactions. In some embodiments, the bias voltage may be increased to increase energy of ions used in the ion bombardment process and, thus, increase a rate of physical etching. The single step anisotropic etching process may result in the profile as shown in dash line in FIG. 111B. The nature of the single step etching process results in a wider top portion and middle portion and a narrower bottom portion of the recess 124. That is, the source/drain regions to be formed in the recess 124 may have a farther proximity at the bottom portion compared to the top portion and middle portion of the source/drain regions. “Proximity” means a distance from the edge of the source/drain to the edge of a channel at the same depth, or a distance from the edge of the source/drain to a location aligned with an edge of an adjacent gate. Therefore, if the edge of the source/drain regions is curved or in an arc chape, the proximity may vary at different levels from the top to the bottom. The non-uniform proximity of source/drain regions may result in uneven resistance along the height of the source/drain regions. More specifically, the profile as shown in dash line may result in a lower resistance at the top and middle portions, and a higher resistance at the bottom portion of the source/drain regions. Junction underlap and weak on-current may occur around the bottom portion of the source/drain regions.

Isotropic etching is relatively difficult to control compared to anisotropic etching, but isotropic etching has a faster etching rate. When microstructures and metal paths require better control, anisotropic etching that provides adequate control if the lattice structure of the silicon wafer is properly oriented is often used. Halogen-containing gases such as Cl₂ has been proved to be an etchant to ensure a high degree of anisotropy in etching. Other gases such as Br-containing gases such as Br₂ and HBr may also be used, but the Br-containing gases may have a lower etching rate. If the etching rate is too low, residues may be deposited on the silicon surface after etching. Therefore, most fluorine-based (F) chemical gases may be used for etching silicon. However, the fluorine atoms may react spontaneously with silicon materials to result in isotropic etching. Based on the specific functions and characteristics of etchants, to obtain a more uniform proximity of the source/drain region, the recess 124 may be formed by a combination of anisotropic etching and isotropic etching. In addition, a second etch step or multiple etch steps may be applied after the first etch step to further improve the profile.

In one embodiment, a two-step etch is used for forming the recess 124. The first etch step may use a combination of an anisotropic etching process and an isotropic etching process. The anisotropic etching process may use a gas mixture from any of HBr, Cl₂, Ar, and other suitable gases. The flow rate of HBr, Cl₂, and Ar may be controlled within the ranges of about 10 to 500 sccm, 10-500 sccm, and 30 to 300 sccm, respectively. The pressure and the temperature of may be controlled with the ranges of about 2 to 80 mTorr and 25 to 100° C., respectively. A bias power of about 50 to 3000 W to control the etching depth may be applied. The duration of the anisotropic etch may last for about 5 to 300 seconds in the first etch step.

The isotropic etch performed in the first etch step may use a gas mixture from any of H₂, CH₄, CH₂F₂, CH₃F, CHF₃, CF₄, SF₆, NF₃, C₄F₈, C₄F₆, Ar, N₂, and other suitable gases. The flow rate of H₂, Ar, and N₂ may be about 50 to 500 sccm, 20 to 300 sccm, and 5 to 200 sccm, respectively. The flow rate of CH₄, CH₂F₂, CH₃F, CHF₃, CF₄, SF₆, NF₃, C₄F₈, C₄F₆ may be controlled within the range of about 5 to 200 sccm. The isotropic etch may be performed with a bias power of about 10 to 300 W and a pressure of about 2 to 80 mTorr at a temperature of about 25 to 100° C. for a duration of about 3 to 150 seconds. In the current etching step, the anisotropic etch performed with a longer duration than the isotropic etch to effectively remove the exposed portion of fin 56 and underlying semiconductor strip 56. The combination of anisotropic etch and isotropic etch changes the dash-line profile in an oval or ellipse shape with a bottom sharp tip presented in dash line into the solid line profile where the sharp bottom tip of the oval or ellipse shape has smoothed with a widened and rounded as shown in FIG. 111B.

To further improve the proximity uniformity of the source/drain regions, additional etch steps may be performed in one embodiment as shown in FIG. 11D. After the first etch step (combination of anisotropic and isotropic etches), a second etch step including a substantially isotropic etching process is performed. The second step etch may use a mixture from any of H₂, CH₄, CH₂F₂, CH₃F, CHF₃, CF₄, SF₆, NF₃, C₄F₈, C₄F₆, Ar, N₂, and other suitable gases. The flow rate of CH₄, CH₂F₂, CH₃F, CHF₃, CF₄, SF₆, NF₃, C₄F₈, C₄F₆ may be controlled within the range of about 5 to 200 sccm. The second step of etching process may be performed with a bias power of about 10 to 300 W and a pressure of about 2 to 80 mTorr at a temperature of about 25 to 100° C. for a duration of about 3 to 150 seconds. The isotropic etching process performed at the second step is performed with a lower bias power than that of the anisotropic etching process in the first etch step, but higher than that of the isotropic etching in the first etch step. The duration is also shorter than the anisotropic etch.

During each etch step, the bias power allows the etchant to be pushed to a desired depth. For example, as the isotropic etching process is to help widen profile at bottom portion of the recess 124, a bias power may be controlled to push the etchant used for the isotropic etching process to a lower position of the recess 124 during the etching process. As a result, the bottom of the recess 124 is widened as shown in FIG. 11D. The first etching step and the second etching step may be performed in-situ or ex-situ. In addition, polymer may be produced while performing the isotropic etching process. When the etching process proceeds towards a deeper position, the polymer deposited on the sidewall at the current depth may be used as a protection to prevent further expansion of the recess 124 at the current depth. The polymer may be cleaned using a cleaning agent such as H₃SO₄ or the like after all etch steps have been performed.

If uniformity of proximity of the source/drain regions after the second etch step needs further improvement, one or more etching processes, for example, more isotropic etching processes, anisotropic etching process, or more combinations of isotropic etching processes and anisotropic etching processes may be performed after the second etch step.

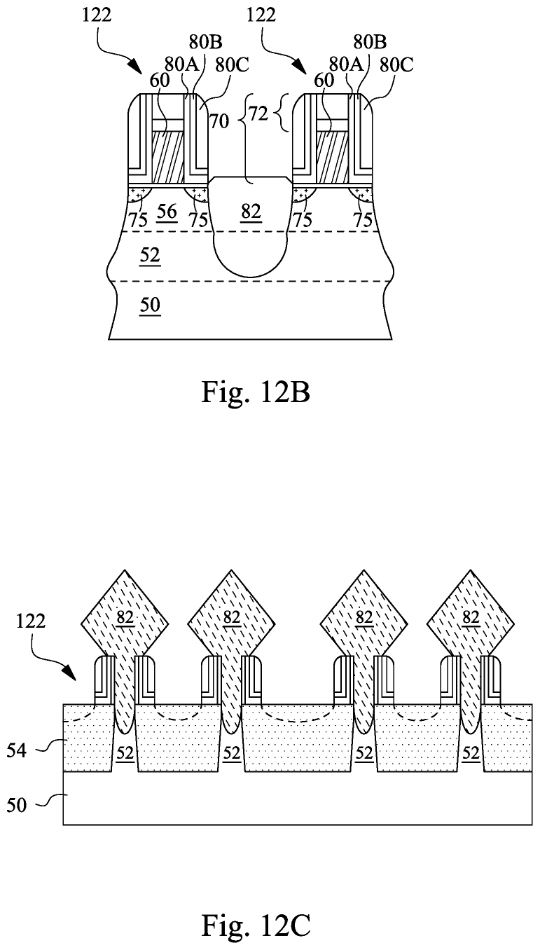

FIGS. 12A, 12B, and 12C illustrate the formation of epitaxial source/drain regions 82. In some embodiments, the epitaxial source/drain regions 82 are epitaxially grown in the recesses 124 using metal-organic CVD (MOCVD), molecular beam epitaxy (MBE), liquid phase epitaxy (LPE), vapor phase epitaxy (VPE), selective epitaxial growth (SEG), a combination thereof, or the like. The epitaxial source/drain regions 82 may include any acceptable material, such as any material that is appropriate for n-type FinFETs or p-type FinFET. For example, if the fin 56 is silicon, the epitaxial source/drain regions 82 may include silicon, SiC, SiCP, SiP, or the like. The epitaxial source/drain regions 82 may have surfaces raised from respective surfaces of the fins 56 and may have facets. The epitaxial source/drain regions 82 are formed in the fins 56 such that each dummy gate 70 is disposed between respective neighboring pairs of the epitaxial source/drain regions 82. In some embodiments. the epitaxial source/drain regions 82 may extend past the fins 56 and into the semiconductor strips 52. In this disclosure, a source region and a drain region are interchangeably used, and the structures thereof are substantially the same. Furthermore, source/drain region(s) may refer to a source or a drain, individually or collectively dependent upon the context.

The material of the epitaxial source/drain regions 82 may be implanted with dopants, similar to the process previously discussed for forming the LDD regions 75, followed by an anneal (see FIGS. 8A, 8B, and 8C). The epitaxial source/drain regions 82 may have an impurity concentration of in a range from about 10¹⁹ cm⁻³ to about 10²¹ cm⁻³. The n-type impurities or p-type impurities for source/drain regions, e.g., the NMOS region or PMOS region, respectively, may be any of the n-type impurities previously discussed. In other embodiments, the material of the epitaxial source/drain regions 82 may be in situ doped during growth. In the current embodiment, each of the source/drain regions 82 is physically separate from other source/drain regions 82. In other embodiments, two or more adjacent source/drain regions 82 may be merged.

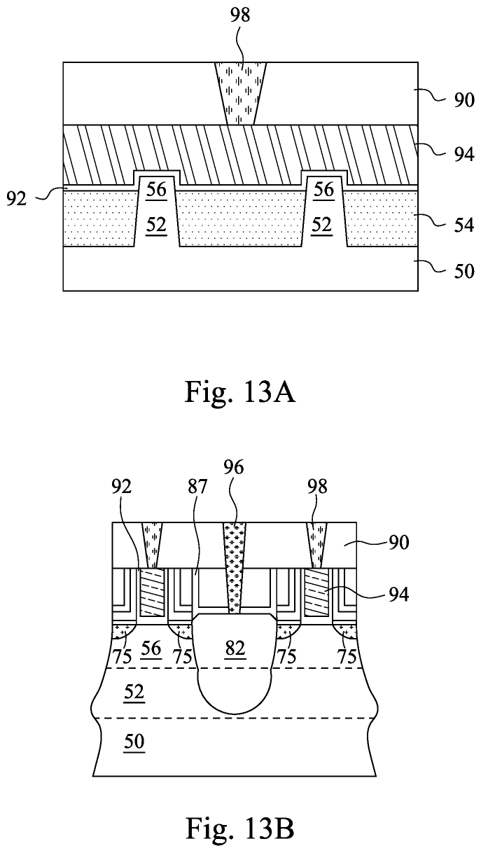

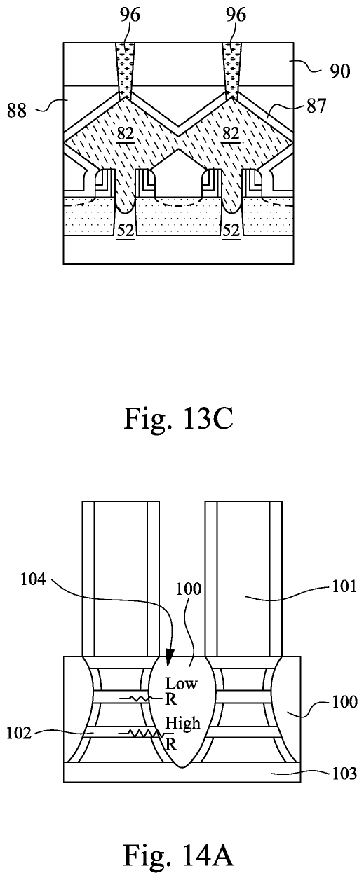

After formation of the source/drain regions 82, the dummy gates 70 are removed. Etch stop layer 87, gate dielectric layers 92, gate electrodes 94, ILD layer 88, ILD layer 90, conductive contacts, including the gate contacts 98 and the source/drain contacts 96 are formed as shown in FIGS. 13A to 13C. Detail description for the processes for forming these structures are omitted in this disclosure.

While the embodiments of this disclosure are discussed with respect to FinFETs, implementations of some aspects of the present disclosure may be used in other processes and/or in other devices, such as planar FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

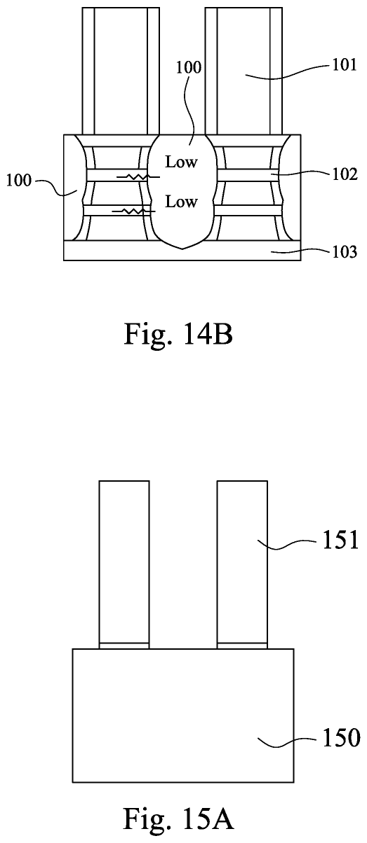

FIGS. 14A and 14B shows a part of a GAA device in an intermediate stage where gates 101 have been formed to extend from the substrate 103 surrounding each channel 100 in a substrate 103 and protrude from the substrate 103. In FIG. 14A, a recess where the source/drain regions 100 are to be formed is formed using a single step anisotropic etching. The single step anisotropic etching may create a recess 104 where in a non-uniform proximity of the source/drain regions 100 with respect to the corresponding channel 100. As a result, the channel lengths between the neighboring source/drain regions 100 vary at different depths of the source/drain region 100. For example, the bottom portion of the source/drain region 100 has a farther proximity, such that the channel length between the neighboring source/drain regions 100 is longer. Therefore, the channel corresponding to the bottom portion of the source/drain regions 100 has a higher resistance, while the channel corresponding to the upper portion has a lower resistance. This cause uneven current flow in operation.

To improve the uniformity in proximity of the source/drain regions 100, two or more etch processes are performed to form a recess for accommodating the source/drain region 100. The first etch step may be performed by combination of anisotropic etching and isotropic etching. In the first etch step, the anisotropic etching may be performed using a process gas mixture from any of HBr, Cl₂, Ar, and other suitable gases. The flow rate of HBr, Cl₂, and Ar may be controlled within the ranges of about 10 to 500 sccm, 10-500 sccm, and 30 to 300 sccm, respectively. The pressure and the temperature of may be controlled with the ranges of about 2 to 80 mTorr and 25 to 100° C., respectively. A bias power of about 50 to 3000 W to control the etching depth may be applied. The duration of the anisotropic etch may last for about 5 to 300 seconds in the first etch step.

The isotropic etch in the first etch step may use a gas mixture from any of H₂, CH₄, CH₂F₂, CH₃F, CHF₃, CF₄, SF₆, NF₃, C₄F₈, C₄F₆, Ar, N₂, and other suitable gases. The flow rate of H₂, Ar, and N₂ may be about 50 to 500 sccm, 20 to 300 sccm, and 5 to 200 sccm, respectively. The flow rate of CH₄, CH₂F₂, CH₃F, CHF₃, CF₄, SF₆, NF₃, C₄F₈, C₄F₆ may be controlled within the range of about 5 to 200 sccm. The isotropic etch may be performed with a bias power of about 10 to 300 W and a pressure of about 2 to 80 mTorr at a temperature of about 25 to 100° C. for a duration of about 3 to 150 seconds. In the current etching step, the anisotropic etch performed with a longer duration than the isotropic etch to effectively remove the exposed portion of fin 56 and underlying semiconductor strip 56.

The second etching stop may include a substantially isotropic etching process using a mixture from any of H₂, CH₄, CH₂F₂, CH₃F, CHF₃, CF₄, SF₆, NF₃, C₄F₈, C₄F₆, Ar, N₂, and other suitable gases. The flow rate of CH₄, CH₂F₂, CH₃F, CHF₃, CF₄, SF₆, NF₃, C₄F₈, C₄F₆ may be controlled within the range of about 5 to 200 sccm. The second step of etching process may be performed with a bias power of about 10 to 300 W and a pressure of about 2 to 80 mTorr at a temperature of about 25 to 100° C. for a duration of about 3 to 150 seconds. The isotropic etching process performed at the second step is performed with a lower bias power than that of the anisotropic etching process in the first etch step. The first etching step and the second etching step may be performed in-situ or ex-situ. In addition, the polymer produced by the etching process may be removed by using agents such as H₃SO₄ or the like.

As shown in FIG. 14B, the source/drain 100 is formed with an improved uniform proximity. That is, the source/drain regions 100 has a more uniform dimension from the top to the bottom. As a result, the channel lengths between the neighboring source/drain region 100 at various depths is substantially constant. The resistance of from the top to the bottom may be maintained constantly low.

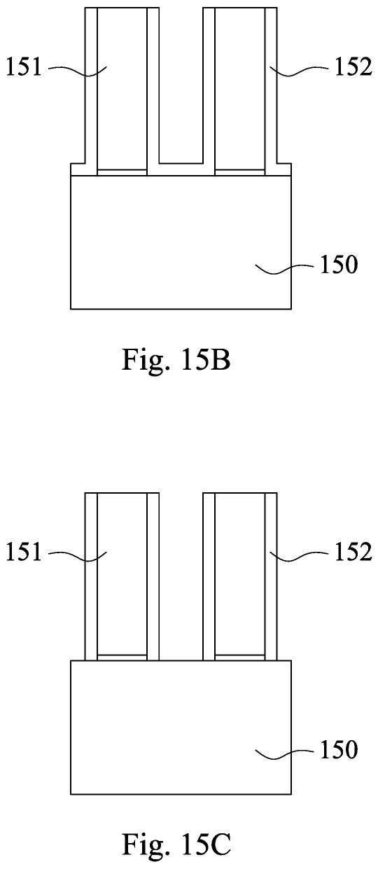

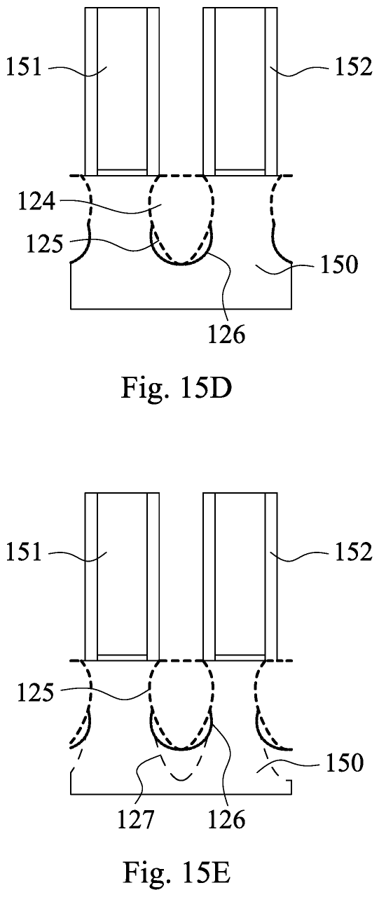

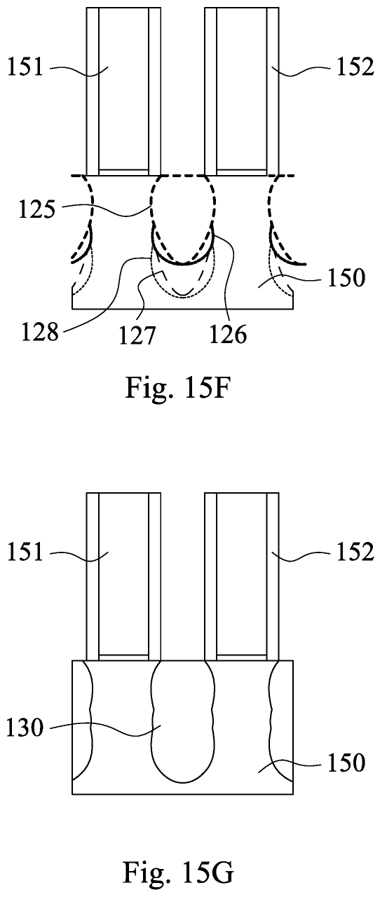

As discussed above, after performing the two-step etch, additional etch steps may be performed until a desired profile of the recess is obtained. FIGS. 15A to 15G are simplified cross sectional drawings showing the multi-step etch for forming the source/drain regions. In FIG. 15A, a pair of gate structures 151 are formed on a substrate 150. In FIG. 15B, a gate spacer layer 152 conformal to a surface profile is formed. In FIG. 15C, the gate spacer layer 152 on the substrate 150 is removed, and a first step etch starts. As shown in FIG. 15D, the first etch step may result in an oval or ellipse profile with a sharp bottom tip represented by the dash line 125. Further in FIG. 15D, a second etch step is performed. Each of the first and second etch may comprise an isotropic etch, an anisotropic etch step, or a combination thereof. The oval profile with a sharp bottom tip 125 shows that the first etch step may include anisotropic etch predominantly, while the profile 126 with a smoothed bottom suggests that the second etch step is more isotropic than anisotropic. In FIG. 15 F, a third etch step is performed to result in the profile 127. Again, the third etch step may be an isotropic etching process, an anisotropic etching process, or a combination of the isotropic etching process and the anisotropic etching process. In the embodiment as shown in FIG. 15F, the profile 127 is deepened from the profile 126 and has a sharp bottom tip. Therefore, the third etch step may be more anisotropic than isotropic. In the fourth etch step, the bottom tip of the profile 127 is rounded and smoothed, while the depth of the recess is not increased as shown in dash line 128. Similar to the first to third etch steps, the fourth etch step may be anisotropic, isotropic, or both anisotropic and isotropic; however, the profile 128 as shown in FIG. 15F suggests that the fourth step may be predominantly isotropic. In FIG. 15G, a source/drain region 130 is formed in the recess 124 with a uniform proximity as shown in FIG. 15G.

The two-step and/or multi-step etch in the embodiments described above creates a recess in the semiconductor substrate, for example, a Si substrate, having a profile with a substantially the width at various depths. The combination of anisotropic and isotropic etching processes provides controls in both vertical direction and lateral direction at various stages. The additional steps of etching processes allow the location where the etching is insufficient to be further etched with a proper control in the desired direction. Therefore, the source/drain regions grown from the recess may have a uniform proximity, and the resistance between the source region and the drain region, that is, the channel resistance, may be maintained with a substantially constant low value.

A method of forming a semiconductor device structure is provided. The method includes forming a plurality of dummy gates over a substrate and performing a first etch step and a second etch step on the substrate exposed between the dummy gates. The first etch step includes an anisotropic etching process and an isotropic etching process. The isotropic etching process may be performed with an etchant being pushed toward a deeper level of the substrate. The second etch step includes an isotropic etching step. A recess is formed in the substrate after performing the first and second etch steps. An epitaxial source/drain region is then grown from the recess.

In one embodiment, an etchant selected from HBr, Cl₂, and Ar is used for forming the anisotropic etching process in the first etch step. The flow rates of HBr, Cl₂, and Ar are controlled within ranges of about 10-500 sccm, 10-500 sccm, and 30-300 sccm, respectively. The anisotropic etching process in the first etch step is performed with a pressure of about 2-80 mTorr and a bias power of about 50 to 3000 W at a temperature of about 25-100° C. The anisotropic etching process is performed for about 5 to 300 seconds and the isotropic etching process in the first etch step is performed for about 3 to 300 seconds in one embodiment.

The isotropic etching process in the first etch step may use an etchant selected from H₂, CH₄, CH₂F₂, CH₃F, CHF₃, CF₄, SF₆, NF₃, C₄F₈, C₄F₆, Ar, N₂, and other suitable gases. The flow rates of H₂, Ar, and N₂ may be controlled within ranges of about 50 to 500 sccm, 20 to 300 sccm, and 5 to 200 sccm, respectively. The flow rate of CH₄, CH₂F₂, CH₃F, CHF₃, CF₄, SF₆, NF₃, C₄F₈, C₄F₆ may be controlled within the range of about 5 to 200 sccm.

The isotropic etching process of the first etch step may be performed with a bias power of about 10 to 300 W and a pressure of about 2 to 80 mTorr at a temperature of about 25 to 100° C. for a duration of about 3 to 150 seconds. The isotropic etching process in the second etch step may use an etchant selected from H₂, CH₄, CH₂F₂, CH₃F, CHF₃, CF₄, SF₆, NF₃, C₄F₈, C₄F₆, Ar, N₂, and other suitable gases. The isotropic etching process of the first etch step with a bias power of about 30 to 1000 W and a pressure of about 2 to 80 mTorr at a temperature of about 25 to 100° C. for a duration of about 3 to 150 seconds. In one embodiment, the second step is performed with a bias power lower than the bias power applied to the anisotropic etching process in the first etch step and higher than the bias power applied to the isotopic etching process in the first etch step.

In one embodiment, the dummy gates are removed and replaced with a plurality of gates after the source/drain regions are formed. An interlayer dielectric layer is formed over the gates and the source/drain regions. Conductive gates and source/drain regions may be formed to connect with the gates and source/drain regions through the interlayer dielectric layer, and a FinFET may be formed.

In another embodiment, a method for forming a GAA semiconductor device comprising the following steps is provided. A plurality of channel structures in formed in a substrate. Each of the channel structures includes a row of channels separated from each other and from the substrate abutting the channel structures by a dielectric layer. A metal gate is formed on each of the channel structures. A source/drain region is formed in the substrate between a pair of immediately neighboring channel structure by forming a recess by a two- or more-step etch and forming epitaxial source/drain regions growing from the recess. The two- or more-step etch includes at least a first etch step and a second etch step performed on the substrate exposed between the metal gates. The first etch step including an anisotropic etching process combined with an isotropic etching process, and the second etch step including an isotropic etching step.

A method of forming a source/drain region in a semiconductor device is provided in yet another embodiment. The method comprises etching a portion of a substrate exposed by a mask layer over the substrate by performing a first etch step and a second etch step. The first etch step includes an anisotropic etching process in combination with an isotropic etching process. The isotropic etching process is performed with a bias power lower than the bias power applied to the anisotropic etching process. The second etch step includes an isotropic etching process. Epitaxial source/drain regions are then grown from a recess created by removing the exposed portion of the substrate. In embodiment, the anisotropic etching process in the first etch step is performed with a bias power of about 50 to 3000 W for about 5 to 300 seconds, and the isotropic etching process in the first etch step is performed with a bias power of about 10 to 300 W for about 3 to 150 seconds. The isotropic etching process in the second etch step is performed with a bias power of about 30 to 1000 W for about 3 to 150 seconds.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of forming a semiconductor device structure, the method comprising:
forming a plurality of dummy gates over a substrate;
performing a first etch step on the substrate exposed between the dummy gates, comprising:
performing an anisotropic etching process; and
performing an isotropic etching process with an etchant being pushed toward a deeper level of the substrate; and
performing a second etch step on the substrate exposed between the dummy gates, the second etch step including an isotropic etching step.

2. The method of claim 1, further comprising:
forming a recess by performing the first etch step and the second etch step; and
forming an epitaxial source/drain region from the recess.

3. The method of claim 1, further comprising using an etchant selected from HBr, Cl₂, and Ar.

4. The method of claim 3, wherein the flow rates of HBr, Cl₂, and Ar are controlled within ranges of about 10-500 sccm, 10-500 sccm, and 30-300 sccm, respectively.

5. The method of claim 1, wherein the anisotropic etching process in the first etch step is performed with a pressure of about 2-80 mTorr and a bias power of about 50 to 3000 W at a temperature of about 25-100° C.

6. The method of claim 5, further comprising performing the anisotropic etching process for about 5 to 300 seconds and the isotropic etching process in the first etch step for about 3 to 300 seconds.

7. The method of claim 1, wherein the isotropic etching process in the first etch step uses the etchant selected from H₂, CH₄, CH₂F₂, CH₃F, CHF₃, CF₄, SF₆, NF₃, C₄F₈, C₄F₆, Ar, N₂, and other suitable gases.

8. The method of claim 7, wherein flow rates of H₂, Ar, and N₂ are controlled within ranges of about 50 to 500 sccm, 20 to 300 sccm, and 5 to 200 sccm, respectively.

9. The method of claim 7, wherein flow rate of CH₄, CH₂F₂, CH₃F, CHF₃, CF₄, SF₆, NF₃, C₄F₈, C₄F₆ is controlled within the range of about 5 to 200 sccm.

10. The method of claim 7, further comprising performing the isotropic etching process of the first etch step with a bias power of about 10 to 300 W and a pressure of about 2 to 80 mTorr at a temperature of about 25 to 100° C. for a duration of about 3 to 150 seconds.

11. The method of claim 1, further comprising performing the isotropic etching process in the second etch step using an etchant selected from H₂, CH₄, CH₂F₂, CH₃F, CHF₃, CF₄, SF₆, NF₃, C₄F₈, C₄F₆, Ar, N₂, and other suitable gases.

12. The method of claim 11, further comprising performing the isotropic etching process of the first etch step with a bias power of about 30 to 1000 W and a pressure of about 2 to 80 mTorr at a temperature of about 25 to 100° C. for a duration of about 3 to 150 seconds.

13. The method of claim 1, further comprising performing the second step with a bias power lower than a bias power applied to the anisotropic etching process in the first etch step and higher than a bias power applied to the isotopic etching process in the first etch step.

14. The method of claim 1, further comprising:
removing the dummy gates;
forming a plurality of gates on the substrate where the dummy gates are removed;
forming an interlayer dielectric layer to over the gates and the source/drain regions; and
forming conductive contacts extending through the interlayer dielectric layer to connect with the source/drain regions and the gates, respectively.

15. The method of claim 1, further comprising forming a fin field effect transistor (FinFET).

16. A method for forming a semiconductor device, comprising:
forming a plurality of channel structures over a substrate, each of the channel structures includes a row of channels separated from each other and from the substrate abutting the channel structures;
forming a metal gate on each of the channel structures;
forming a source/drain region in the substrate between a pair of immediately neighboring channel structure by:
forming a recess by a two- or more-steps etch, including at least:
a first etch step on the substrate exposed between the metal gates, the first etch step including an anisotropic etching process and an isotropic etching process; and
a second etch step on the substrate exposed between the metal gates, the second etch step including an isotropic etching step; and
forming epitaxial source/drain regions growing from the recess.

17. The method of claim 15, further comprising manufacturing a gate all around (GAA) device.

18. A method of forming a source/drain region in a semiconductor device, comprising:
etching a portion of a substrate exposed by a mask layer over the substrate;
removing the exposed portion of the substrate by performing a first etch step, which includes
an anisotropic etching process; and
an isotropic process in combination with the anisotropic etching process with a bias power different from a bias power applied to the anisotropic etching process;
further removing the exposed portion of the substrate by performing a second etch step; and
growing epitaxial source/drain regions from a recess created by removing the exposed portion of the substrate.

19. The method of claim 18, wherein the anisotropic etching process in the first etch step is performed with a bias power of about 50 to 3000 W for about 5 to 300 seconds, and the isotropic etching process in the first etch step is performed with a bias power of about 10 to 300 W for about 3 to 150 seconds.

20. The method of claim 18, wherein the isotropic etching process in the second etch step is performed with a bias power of about 30 to 1000 W for about 3 to 150 seconds.
